(19) United States
(12) Patent Application Publication
(10) Pub. No.: US 2001/0020731 A1
(43) Pub. Date: Sep. 13, 2001

(54) Semiconductor devices

(76) Inventor: Takashi Takamura, Chimo-shi (JP)

Correspondence Address: KONRAD RAYNES & VICTOR, LLP, 315 SOUTH BEVERLY DRIVE, SUITE 210, BEVERLY HILLS, CA, 90212, US

(21) Appl. No.: 09/735,738

(22) Filed: Dec. 13, 2000

(30) Foreign Application Priority Data
Dec. 13, 1999 (JP) 11-353068

(51) Int. Cl. H01L 29/00; H01L 29/40

(52) U.S. Cl. 257/621; 257/531

(57) ABSTRACT

Certain embodiments relate to a microwave monolithic integrated circuit using a silicon substrate in which parasitic capacitances between inductors and a silicon substrate are sufficiently reduced. A semiconductor device may include a silicon substrate 1, a CMOSFET 200 formed on the silicon substrate 1, and an inductor 100 formed over the silicon substrate 1 through an insulation layer 50. A through hole 300 is formed in the silicon substrate 1 in a portion below the inductor 100.

Japanese patent application no. 11-353068, filed Dec. 13, 1999, is hereby incorporated by reference in its entirety. U.S. patent application Ser. No. ______, filed on Dec. 13, 2000, entitled “Inductors, Semiconductor Devices, and Methods of Manufacturing Semiconductor Devices,” invented by Takashi Takamura, docket no. 15.26/5324, is hereby incorporated by reference in its entirety.

### TECHNICAL FIELD

The present invention relates to semiconductor devices, including a semiconductor device having a silicon substrate and active elements such as transistors and passive elements such as inductors (circuit elements having inductance) formed on the silicon substrate.

### BACKGROUND

To make smaller and lighter radio communication apparatuses such as cellular phones, it is effective to reduce the power consumption of a high frequency amplification unit in the apparatus, to thereby make a smaller and lighter battery that is mounted on the apparatus. In this connection, a microwave monolithic integrated circuit has been under development. The microwave monolithic integrated circuit includes passive elements such as inductors formed together with active elements such as transistors within an integrated circuit. In particular, from the viewpoint of the price and reliability of integrated circuits, the realization of a microwave monolithic integrated circuit using a silicon substrate is expected.

In manufacturing a CMOSFET (complementary metal-oxide semiconductor field effect transistor), a silicon substrate having a specific resistance of 10-15 Ω is normally used. Therefore, a microwave monolithic integrated circuit using a silicon substrate suffers a problem in that parasitic capacitances between the inductors and the silicon substrate are large.

PCT publication No. WO96/27905 describes one solution to the problem. According to the publication, a groove is formed in an upper surface of a silicon substrate in a region where passive elements (inductors and the like) are formed, silicon oxide is filled in the groove, and passive elements are formed on the silicon oxide. The publication describes that, as a result, an insulating member having a sufficient thickness is formed between the passive elements and the silicon substrate, and parasitic capacitances between the passive elements and the silicon substrate can be sufficiently reduced.

The publication also describes the use of an SOI (silicon on insulator) substrate in which a silicon oxide film and a monocrystal silicon oxide film are provided in this order on a silicon substrate. The publication further describes removing a portion of the monocrystal silicon oxide film on the silicon oxide film, forming a passive element on the silicon oxide film that is exposed, and forming an active element on the monocrystal silicon oxide film that is not removed.

The technique described in the above publication includes steps of forming the groove in an upper surface of the silicon substrate. After the groove is filled with silicon oxide, a step needs to be conducted to planarize the upper surface of the filled silicon oxide by a CMP (chemical mechanical polish) method. However, a concave recess is likely formed in a central area of the upper surface of the silicon oxide that is filled in the groove, and therefore there is a problem in that planarization of the wafer surface is difficult.

Also, the method using the SOI substrate does not sufficiently achieve the effect of reducing parasitic capacitances between the passive elements and the silicon substrate. To solve this problem, Japanese Laid-open patent application HEI 9-270515 describes the use of a high resistance silicon substrate having a specific resistance of more than 1 kΩcm. However, it is very difficult to obtain a high resistance silicon substrate having a specific resistance of more than 1 kΩcm. Also, the specific resistance value of 1 kΩcm is generally not enough for an insulation member.

### SUMMARY

One embodiment relates to a semiconductor device including a substrate, an active element formed on or over the substrate and a passive element formed on or over the substrate through an insulation layer. A through hole is formed in a lower portion of the substrate below an area where the passive element is formed, the through hole being formed by an etching from a back side of the substrate, and an interior of the through hole is in an insulating state.

Another embodiment relates to a semiconductor device including a substrate, an active element formed on or over the substrate and a passive element formed on or over the substrate through an insulation layer. At least one column-like structure is formed in a lower portion of the substrate below an area in an upper surface of the substrate where the passive element is formed, the column-like structure in the lower portion extending to a predetermined depth and formed by etching the substrate with a predetermined pattern, wherein an insulation material fills at least part of a region removed from the substrate by the etching.

Another embodiment relates to a semiconductor device comprising a substrate, an active element and a passive element. The active element is located on or above the substrate. The substrate including an opening extending a depth therein. The passive element is located directly above at least a portion of the opening and separated from the opening by an insulating layer. The opening includes an insulating region therein.

### BRIEF DESCRIPTION OF THE DRAWINGS

Certain embodiments of the invention are described with reference to the accompanying drawings which, for illustrative purposes, are schematic and not necessarily drawn to scale.

FIG. 1 schematically shows a cross section of a semiconductor device in accordance with a first embodiment of the present invention.

FIG. 2 illustrates a method for manufacturing the semiconductor device shown in FIG. 1.

FIG. 3 illustrates a method for manufacturing the semiconductor device shown in FIG. 1.

FIG. 4 illustrates a method for manufacturing the semiconductor device shown in FIG. 1, and shows a positional relation between a through hole in a silicon substrate and an inductor (passive element).

FIG. 5 schematically shows a cross section of a semiconductor device in accordance with another embodiment of the present invention.

FIG. 6 illustrates a method for manufacturing the semiconductor device shown in FIG. 5.

FIG. 7 illustrates a method for manufacturing the semiconductor device shown in FIG. 5.

FIG. 8 illustrates a method for manufacturing the semiconductor device shown in FIG. 5.

### DETAILED DESCRIPTION

Certain embodiments of the present invention relate to a microwave monolithic integrated circuit using a silicon substrate in which parasitic capacitances between passive elements such as inductors and the silicon substrate are substantially reduced without causing problems that may make planarization of the wafer surface difficult.

Certain embodiments of the present invention provide a semiconductor device comprising a silicon substrate, an active element formed on or over the silicon substrate, and a passive element formed over the silicon substrate through an insulation layer, characterized in that a through hole is formed in a lower portion of the silicon substrate below an area where the passive element is formed, the through hole being formed by an etching from a back side of the substrate, and an interior of the through hole being in an insulating state.

By the semiconductor device embodiment described above, silicon is not present in a lower portion below a region where a passive element is formed, and the portion is in an insulating state. As a result, parasitic capacitances are not generated in this portion.

Also, an embodiment of the present invention provides a semiconductor device comprising a silicon substrate, an active element formed on or over the silicon substrate, and a passive element formed over the silicon substrate through an insulation layer, characterized in that a column-like silicon is formed in a lower portion of the silicon substrate below an area in an upper surface of the substrate where the passive element is formed, the column-like silicon in the lower portion extending to a predetermined depth and formed by etching the silicon with a predetermined pattern, wherein an insulation member is filled in a portion where the silicon is removed by the etching.

By the semiconductor device embodiment described above, the silicon substrate has a portion that is filled with an insulation member to a predetermined depth below an area where a passive element is formed. As a result, parasitic capacitances between the passive element and the silicon substrate become smaller, compared to the one that does not have such an area. Also, because the column-like silicon remains, the wafer surface is more likely to be planarized, compared to the one that does not have such a column-like silicon.

In certain embodiments, when the semiconductor device is made with a SOI substrate, active elements are formed on a monocrystal silicon film that is present over the silicon substrate through an insulation film.

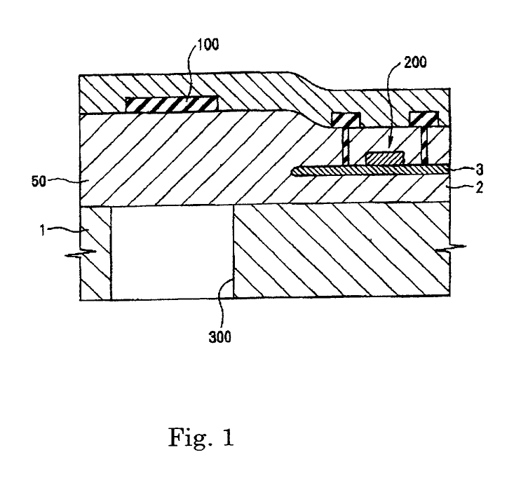

Certain embodiments of the present invention will be described below with reference to FIGS. 1-8.

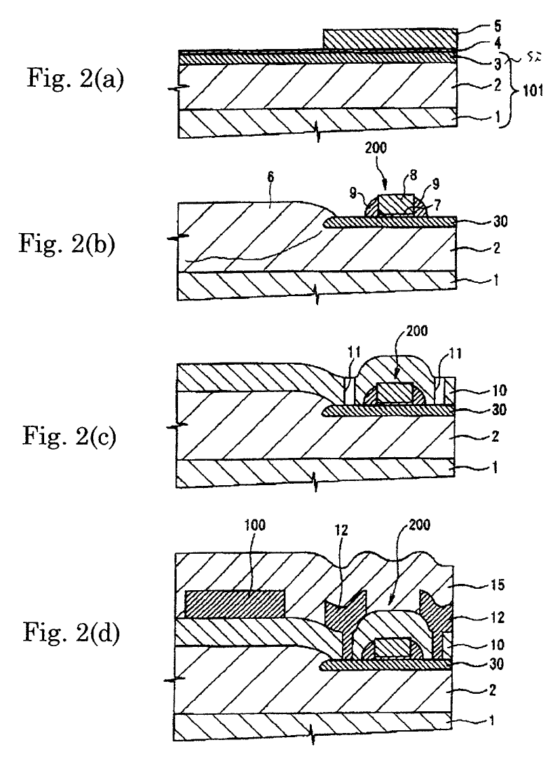

FIG. 1 schematically shows a cross section of a semiconductor device in accordance with a first embodiment of the present invention. The semiconductor device preferably has a silicon substrate 1, a CMOSFET (active element) 200 formed on the silicon substrate 1, and an inductor (passive element) 100 formed over the silicon substrate 1 through an insulation layer 50. A through hole 300 is formed in the silicon substrate 1 in an area below the inductor 100. The semiconductor device of this embodiment is manufactured using an SOI substrate, and therefore, the CMOSFET 200 is not formed directly on the silicon substrate 1, but is formed on a monocrystal silicon film 3 over a silicon oxide film 2. A method of manufacturing the silicon semiconductor device will be described with reference to FIGS. 2-4.

As shown in FIG. 2(a), an SOI substrate 101 includes a silicon substrate 1, a silicon oxide film 2 and a monocrystal silicon film 3 provided in this order. The silicon substrate 1 has a preferred thickness of about 600 μm, the silicon oxide film 2 has a preferred thickness of about 0.4-0.6 μm. Also, the monocrystal silicon film 3 has a preferred thickness of about 0.04-0.3 μm.

A thin oxide film 4 is formed on the monocrystal silicon film 3, and a mask 5 composed of a material such as a silicon nitride film is formed on the thin oxide film 4. Exposed portions of the thin oxide film 4 are removed, and then exposed portions of the monocrystal silicon film 3 are thermally oxidized, to thereby form LOCOS films 6 at an element isolation position and in a region where an inductor 100 is formed. The LOCOS film 6 connects to the silicon oxide film 2 below, as shown in FIG. 2(b).

Next, an impurity is doped in an element region 30 that is isolated by the LOCOS film 6, a gate oxide film 7 is formed, a gate electrode 8 composed of polysilicon is formed, impurity doping for forming an LDD (Lightly Doped Drain) region is conducted, sidewalls 9 are formed, and impurity doping is conducted in source and drain regions. As a result, the CMOSFET 200 is formed in the element region 30 composed of a monocrystal silicon film. Each of the steps may be conducted using a method known in the art. FIG. 2(b) shows a state in which the above-described steps have been conducted. Referring to FIG. 2(b), either of p-channel MOSFET and n-channel MOSFET that form the CMOSFET 200 is omitted.

Then, a silicon oxide film 10 is formed by a CVD method over the surface of the silicon substrate 1 in the state shown in FIG. 2(b). The silicon oxide film 10 is subject to ordinary photolithography process and etching process to form contact holes 11 for source and drain electrodes. FIG. 2(c) shows a state in which the above-described processes have been conducted.

Then, a thin film composed of an aluminum alloy is formed by a sputtering method over the entire surface of the silicon substrate 1 in the state shown in FIG. 2(c). The thin film is subject to ordinary photolithography process and etching process to thereby form a pattern for the inductor 100 and wirings for source and drain electrodes 12 and the like. Then, a silicon nitride film 15 is formed as a protection film by a CVD method over the entire surface of the silicon substrate 1. FIG. 2(d) shows a state in which the steps described above have been conducted.

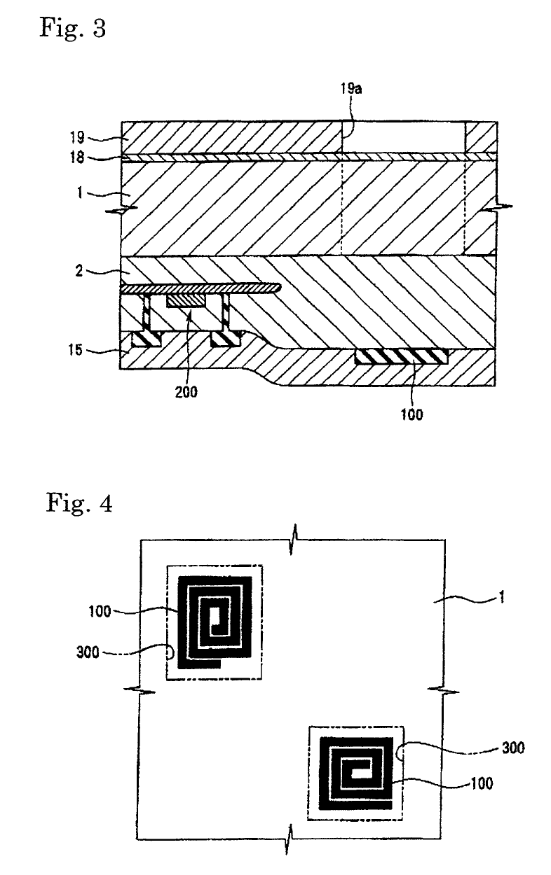

As shown in FIG. 3, a silicon oxide film 18 is formed to a preferred thickness of about 1 μm by a CVD method on a rear (or bottom) surface of the silicon substrate 1. Then, a resist pattern 19 is formed on the silicon oxide film 18 by an ordinary photolithography. The resist pattern 19 has an opening section 1 9a at a position where the inductor 100 is formed with a size covering the inductor 100 and some peripheral margins around the inductor 100. The margin has a width of about 100 μm, for example, when the inductor 100 is a rectangular coil having a line width of about 50 μm.

The silicon oxide film 18 and the silicon substrate 1 are removed by an etching using the resist pattern 19 as a mask. The etching is conducted from the rear side of the substrate in the thickness direction. For the etching of the silicon oxide film 18, a dry etching with a fluorocarbon gas is conducted. For the etching of the silicon substrate 1, a dry etching with a chlorine gas is conducted. By this process, a through hole 300 is formed in the silicon substrate 1 below an area where the inductor 100 is formed.

It is noted that the dry etching with a chlorine gas results in a great selection ratio between silicon and silicon oxide. Therefore, a strict control on the etching time and the like may not be particularly required, because the silicon oxide film 2 is not etched after the silicon in the silicon substrate 1 located at the opening section 1 9a is removed by the etching from the rear surface of the substrate in the thickness direction. Furthermore, the silicon oxide film 18 provided on the rear surface of the silicon substrate 1 protects the resist pattern 19 from deterioration.

FIG. 4 is a plan view showing the positional relation between the through hole 300 and the inductor 100. As shown in the figure, when plural inductors 100 are formed at location separated from one another, a through hole 300 is formed in the silicon substrate 1 in a portion under each of the areas where the inductors 100 are formed.

In the manner described above, the semiconductor device shown in FIG. 1 is obtained. The silicon oxide film 2 of the SOI substrate 101, the LOCOS film 6 formed thereon, and the silicon oxide film 10 formed on the LOCOS film 6 are generally represented by the insulation layer 50 shown in FIG. 1. It is noted that the through hole 300 may be filled with an insulation material such as polyimide resin, silicon oxide. Alternatively, it may not be filled with anything. As a result, when the semiconductor device is cut as a semiconductor chip and enclosed in a package, the interior of the through hole 300 is kept in an insulating state.

According to the semiconductor device described above, the through hole 300 is formed in the silicon substrate 1 in a portion under a region where the inductor 100 is formed. Therefore, silicon is not present in the area below the region where the inductor 100 is formed. Also, the interior of the through hole 300 is in the insulating state. As a result, parasitic capacitances are inhibited or not generated between the inductor 100 and the silicon substrate 1. Therefore, when the inductor 100 is a high-frequency coil or a high-frequency transformer, a high-frequency amplification circuit with a high performance and a low loss is obtained.

The through hole 300 is formed after the inductor 100 and the CMOSFET 200 are formed by etching the silicon substrate 1 from the rear side of the silicon substrate 1. As a result, the formation of the inductor 100 and the CMOSFET 200 is not adversely affected.

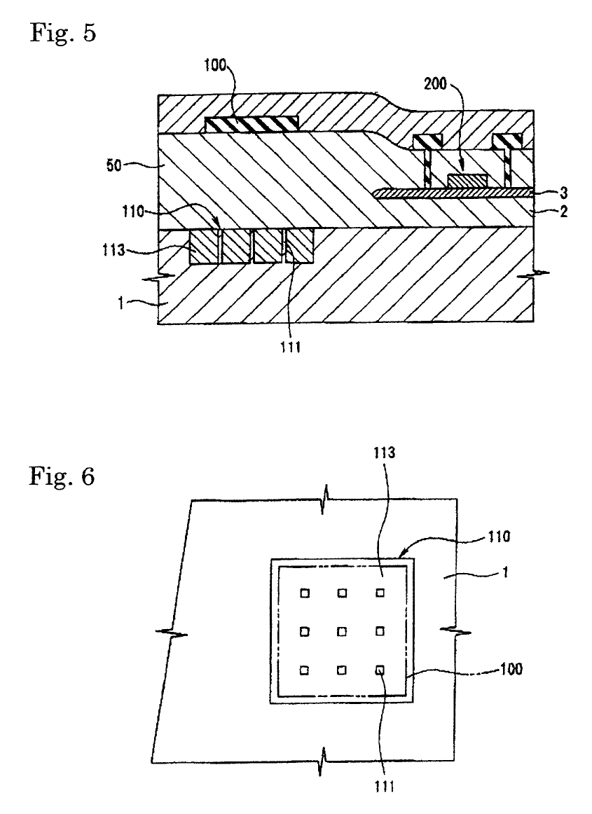

Next, a semiconductor device in accordance with a second embodiment of the present invention is described with reference to FIGS. 5-8. FIG. 5 schematically shows a cross section of the semiconductor device of the second embodiment.

The semiconductor device has a silicon substrate 1, a CMOSFET 200 formed on the silicon substrate 1, and an inductor 100 formed over the silicon substrate 1 through an insulation layer 50. The inductor 100 is provided on the upper surface of the silicon substrate 1, and a portion 110 below the inductor 100 is processed to a predetermined depth in a specified configuration.

FIG. 6 shows a plan view of the silicon substrate 1 that includes the portion 110. The portion 110 is provided with a size that covers the inductor 100 and an appropriate peripheral margin around the inductor 100. The portion 110 has columns of silicon 111 remained as a result of an etching. Silicon oxide 113 is filled in portions where the silicon is removed by the etching.

Also, since an SOI substrate is used in manufacturing the semiconductor device of this embodiment, the CMOSFET 200 is not formed directly on the silicon substrate 1, but is formed on a monocrystal silicon film 3 over a silicon oxide film 2.

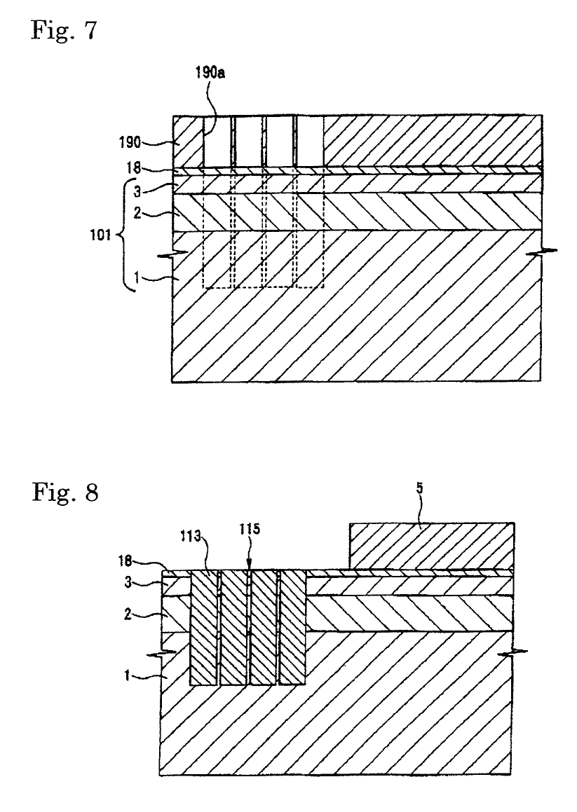

For manufacturing the semiconductor device, first, as shown in FIG. 7, a silicon oxide film 18 is formed to a preferred thickness of about 1 μm by a CVD method on a monocrystal silicon film 3 of an SOI substrate 101. The SOI substrate 101 is composed of a silicon substrate 1, a silicon oxide film 2 and the monocrystal silicon film 3. Then, a resist pattern 190 is formed on the silicon oxide film 18 by an ordinary photolithography process. The resist pattern 190 has an opening 190a at a location where an inductor 100 composed of a resist film is formed. The opening 190a is provided in a manner that one or more columns of silicon 111 shown in FIG. 6 remain.

The silicon oxide film 18, the monocrystal silicon film 3, the silicon oxide film 2 and the silicon substrate 1 are etched, using the resist pattern 190 as a mask. First, the silicon oxide film 18 is etched across its entire area in the depth direction, using a fluorocarbon gas as an etching gas. Then, the etching gas is switched to a chlorine gas, and the monocrystal silicon film 3 is etched across its entire area in the depth direction. Then, the etching gas is switched to a fluorocarbon gas, and the silicon oxide film 2 is etched across its entire area in the depth direction. Then, the etching gas is switched to a chlorine gas, and the silicon substrate 1 is etched to a specified depth.

By the process described above, a patterned configuration including the columns of silicon 111 shown in FIG. 6 is formed at a location where the inductor 100 is formed. The pattern extends from the silicon oxide film 18 to a specified depth in the silicon substrate 1. Then, the resist pattern 190 is removed and, as shown in FIG. 8, spaces created by the formation of a column pattern 115 may be filled with a variety of materials, including, for example, insulators such as silicon oxide 113 by an SOG (Spin On Glass) method. Then, the surface of the silicon oxide film 18 is planarized by a CMP method. Other examples of materials that may fill the spaces created between the pattern 115 include a low dielectric such as an SiOF film and a porous SiOx film.

Next, in a similar manner as described with reference to the first embodiment, a mask 5 composed of a silicon nitride film is formed on the silicon oxide film 18. In this state, exposed portions of the silicon oxide film 18 are removed, and then exposed portions of the monocrystal silicon film 3 are thermally oxidized, to thereby form LOCOS films 6 at an element isolation position and in a region where an inductor 100 is formed. Then, the CMOSFET 200 and the inductor 100 are formed in a similar manner as described above in the first embodiment.

In this manner, the semiconductor device shown in FIG. 5 is obtained. The silicon oxide film 2 of the SOI substrate, the LOCOS film (such as element 6 shown in FIG. 2) formed thereon, the silicon oxide film (such as element 10 shown in FIG. 2) formed on the LOCOS film, and the silicon oxide 113 filled in the spaces created in the silicon oxide film 2 are generally represented by the insulation layer 50 shown in FIG. 5.

In accordance with the semiconductor device described above, the silicon substrate 1 has the inductor 100 on the upper surface thereof and the portion 1 10 below the inductor 100. The portion 110 is filled with silicon oxide (insulation material) 113 extending to a specified depth in the substrate 1. As a result, parasitic capacitances between the inductor 100 and the silicon substrate 1 are reduced accordingly. Therefore, when the inductor 100 is a high-frequency coil or a high-frequency transformer, a high-frequency amplification circuit with a high performance and a low loss is obtained.

Also, the columns of silicon 11 1 remain in the lower portion 110 below the inductor 100 that is provided on the upper surface of the silicon substrate 1. As a result, the formation of a concave recess is inhibited when the surface of the silicon substrate film 18 is planarized by a CMP method. Therefore, the wafer surface is more readily planarized, as compared to the prior art method.

For example, when the coil width of the inductor 100 is 50 μm, the depth of etching in the silicon substrate 1 is about 30 μm to make the characteristic impedance of the inductor 100 to be 50 Ω. Also, the line width of the pattern of the columns of silicon 111 is about 1 μm, and a separation between the patterns is about 10 μm.

It is noted that, in this embodiment, the lower portion 110 below the inductor 100 that is provided on the upper surface of the silicon substrate 1 is etched to leave only the columns of silicon 111. However, the pattern of the silicon to be remained in the portion 110 is not limited to this embodiment. For example, a lattice pattern may be formed to leave the columns of silicon 111 and beams of silicon that connect the columns of silicon 111 in horizontal and lateral directions. Also, when only the columns of silicon 111 are remained, the pattern is not limited to the one shown in FIG. 6 in which columns are aligned in horizontal and lateral directions. For example, a different pattern may be used so that columns are located at positions diverted from one another in horizontal and lateral directions.

It is noted that, in the semiconductor devices formed using an SOI substrate, a CMOSFET 200 that is an active element is not formed directly on the silicon substrate 1, but is formed on a monocrystal silicon film 3 over a silicon oxide film 2. However, the present invention is not limited to these embodiments, but includes semiconductor devices in which an active element such as a CMOSFET is formed directly on a silicon substrate.

As described above, certain embodiments of the present invention provide a semiconductor device comprising a silicon substrate, an active element formed on the silicon substrate, and a passive element formed over the silicon substrate through an insulation layer, which does not create problems that make it difficult to planarize the wafer surface, and which substantially lowers parasitic capacitances between the active element and the silicon substrate. As a result, a high-frequency amplification circuit with a high performance and a low loss may be obtained, as a monolithic integrated circuit using a silicon substrate. It should be appreciated that various modifications may be made while remaining within the scope of embodiments of the present invention.

What is claimed:

1. A semiconductor device comprising a substrate, an active element formed on or over the substrate and a passive element formed over the substrate through an insulation layer, wherein a through hole is formed in a lower portion of the substrate below an area where the passive element is formed, the through hole being formed by an etching from a back side of the substrate, and an interior of the through hole being in an insulating state.

2. A semiconductor device comprising a substrate, an active element formed on or over the substrate and a passive element formed on or over the substrate through an insulation layer, wherein at least one column-like structure is formed in a lower portion of the substrate below an area in an upper surface of the where the passive element is formed, the column-like structure in the lower portion extending to a predetermined depth and formed by etching the substrate with a predetermined pattern, wherein an insulation material fills at least part of a region removed from the substrate by the etching.

3. A semiconductor device according to claim 1, wherein the active element is formed on a monocrystal silicon film that is present over the substrate through an insulation film.

4. A semiconductor device according to claim 2, wherein the active element is formed on a monocrystal silicon film that is present over the substrate through an insulation film.

5. A semiconductor device according to claim 1, wherein the active element is formed in direct contact with the substrate.

6. A semiconductor device according to claim 2, wherein the active element is formed in direct contact with the substrate.

7. A semiconductor device according to claim 1, wherein the passive device is an inductor.

8. A semiconductor device according to claim 2, wherein the passive device is an inductor.

9. A semiconductor device comprising a substrate, an active element and a passive element,
the active element located on or above the substrate;
the substrate including an opening extending a depth therein;
the passive element located directly above at least a portion of the opening and separated from the opening by an insulating layer; and
an insulating region in the opening.

10. A semiconductor device as in claim 9, wherein the opening extends at least partially around a portion of the substrate that is positioned directly under the passive element and separated from the passive element by the insulating layer.

11. A semiconductor device as in claim 10, wherein the portion of the substrate has a column-shaped structure.

12. A semiconductor device as in claim 9, wherein a plurality of column-shaped substrate structures are located directly under the passive element and separated from the passive element by the insulating layer.

13. A semiconductor device as in claim 9, further comprising an insulating material selected from the group of polyimide resin and silicon oxide is disposed in the opening in the substrate.

14. A semiconductor device as in claim 9, where the opening is formed to surround at least one substrate structure.

15. A semiconductor device as in claim 9, wherein the active device is a transistor and the passive device is an inductor.

16. A semiconductor device as in claim 9, wherein the insulating layer comprises multiple insulating films.

17. A semiconductor device as in claim 12, wherein the passive element is an inductor and the plurality of substrate structures have a width of about 1 micron and are spaced about 10 microns apart from each other.

18. A semiconductor device as in claim 9, wherein the opening is larger in area than the passive element.

19. A semiconductor device as in claim 9, further comprising an insulating material selected from the group of spin-on-glass, an SiOF film, and a porous silicon oxide film.

20. A semiconductor device as in claim 9, wherein the substrate comprises silicon.
